(19) United States
(12) Patent Application Publication
(10) Pub. No.: US 2012/0060891 A1
(43) Pub. Date: Mar. 15, 2012

(54) PHOTOVOLTAIC DEVICE

(76) Inventors: Benyamin Buller, Sylvania, OH (US); Douglas Dauson, Perrysburg, OH (US); Chungho Lee, San Jose, CA (US); Scott Mills, Perrysburg, OH (US); Dale Roberts, Temperance, MI (US); Rui Shao, Sylvania, OH (US); Zhibo Zhao, Novi, MI (US); Keith Burrows, Mineral Point, WI (US); Annette Krisko, Spring Green, WI (US)

(21) Appl. No.: 13/209,753

(22) Filed: Aug. 15, 2011

Related U.S. Application Data
(60) Provisional application No. 61/373,685, filed on Aug. 13, 2010.

(51) Int. Cl. H01L 31/0224; H01L 31/042; H01L 31/18

(52) U.S. Cl. 136/244; 438/85; 136/256; 257/E31.003

(57) ABSTRACT

A multilayered structure including a first barrier layer adjacent to a substrate, a barrier bi-layer adjacent to the first barrier layer, the barrier bi-layer comprising a second barrier layer and a third barrier layer, a transparent conductive oxide layer adjacent to the barrier bi-layer, and a buffer layer adjacent to the transparent conductive oxide layer and method of forming the same. A multilayered substrate including a barrier layer structure having a plurality of barrier layers being alternating layers of low refractive index material and high refractive index material, a transparent conductive oxide layer adjacent to the barrier bi-layer and a buffer layer adjacent to the transparent conductive oxide layer. The multilayered structure may serve as a front contact for photovoltaic devices.

### CLAIM OF PRIORITY

This application claims priority under 35 U.S.C. §119(e) to U.S. Provisional Patent Application Ser. No. 61/373,685 filed on Aug. 13, 2010, which is hereby incorporated by reference in its entirety.

### TECHNICAL FIELD

The disclosed embodiments relate to photovoltaic devices with built-in color suppression and reflection reduction layers and methods of production.

### BACKGROUND

Photovoltaic devices can include multiple layers created on a substrate (or superstrate). For example, a photovoltaic device can include a barrier layer, a transparent conductive oxide (TCO) layer, a buffer layer and a semiconductor layer (or active layer) formed in a stack on a substrate. Each layer may in turn include more than one layer or film. For example, the semiconductor layer can include a first film including a semiconductor window layer formed on the buffer layer and a second film including a semiconductor absorber layer, formed on the semiconductor window layer. The semiconductor window layer can allow the penetration of solar radiation to the absorber layer, which converts solar energy to electricity. Each layer can cover all or a portion of the device and/or all or a portion of the layer or substrate underlying the layer. For example, a “layer” can include any amount of any material that contacts all or a portion of a surface.

Photovoltaic devices can be formed on optically transparent substrates, such as glass. Because glass is not conductive, a front contact, which may include a multilayered stack consisting of a transparent conductive oxide (TCO) layer, is typically deposited between the substrate and the semiconductor bi-layer. A smooth buffer layer can be deposited between the TCO layer and the semiconductor window layer to decrease the likelihood of irregularities occurring during the formation of the semiconductor window layer. Additionally, a barrier layer can be incorporated between the substrate and the TCO layer to lessen diffusion of sodium or other contaminants from the substrate to the semiconductor layers, which could result in degradation and delamination. The barrier layer can be transparent, thermally stable, with a reduced number of pin holes and having high sodium-blocking capability and good adhesive properties.

A thin-film photovoltaic device may include a multilayer structure having different barrier materials. As light transmits from the glass surface to the active layers, the interference of reflected light at various interfaces can cause strong undulation of reflected light. This is particularly true for thin-film devices based on sputtered multilayer stacks in which the interfaces are generally smooth. The reflected light represents a true loss of light, as it does not reach the p-n junction of the photovoltaic device. Further, strongly interfered reflection light may cause uneven colors, which may adversely affect visual appearance. Therefore it would be highly desirable to minimize the intensity of reflected light and interference and provide a photovoltaic device with improved efficiency.

### DESCRIPTION OF DRAWINGS

FIG. 1 is a schematic of an example embodiment of a multilayered structure as a front contact for a photovoltaic device.

FIG. 2 is a schematic of a photovoltaic device having multiple layers.

FIG. 3 is a schematic of an example embodiment of a multilayered structure as a front contact for a photovoltaic device.

FIG. 4 is a schematic of a photovoltaic device having multiple layers.

FIG. 5 is a schematic of a system for generating electricity.

FIG. 6 is a flowchart of a method of forming a multilayered structure.

FIG. 7 is a flowchart of a method of forming a photovoltaic device.

### DETAILED DESCRIPTION

In the following detailed description, reference is made to the accompanying drawings which form a part hereof, and in which is shown by way of illustration specific embodiments that may be practiced. These embodiments are described in sufficient detail to enable those skilled in the art to make and use them, and it is to be understood that structural, logical or procedural changes may be made to the specific embodiments disclosed without departing from the spirit and scope of the invention.

Disclosed embodiments reduce the average reflection loss and the magnitude of interference in the visible spectrum by incorporating a bi-layer of high refractive index material and a low refractive index material, with properly designed thickness for each layer, into the photovoltaic device. Methods of manufacturing multilayered structures and photovoltaic devices incorporating the same are also disclosed.

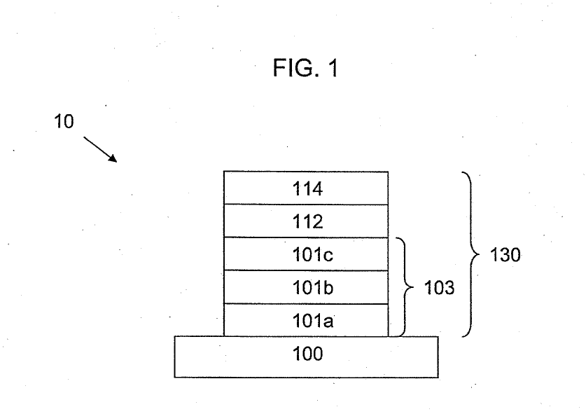

An example embodiment of a multilayered structure 10 is shown in FIG. 1. Multilayered structure 10 may serve as a front contact for a photovoltaic device. Barrier tri-layer 103 is formed adjacent to a substrate 100. Barrier tri-layer 103 includes barrier layers 101a, 101b, 101c. A transparent conductive oxide layer 112 is formed adjacent to barrier tri-layer 103. A buffer layer 114 is formed adjacent to transparent conductive oxide layer 112.

Substrate 100 is formed of any suitable material, including, for example, a glass (e.g., soda-lime glass). Substrate 100 may be formed to be any suitable thickness, including, for example, more than about 2 mm, more than about 3 mm, or less than about 5 mm.

Barrier layers 101a, 101b, 101c include alternating layers of relatively low and high refractive index materials. Barrier layer 101a includes a low refractive index material formed adjacent to (e.g., directly on) substrate 100. The low refractive index material may include any suitable barrier material, including, for example, silicon oxide, aluminum-doped silicon oxide or silicon oxynitride. Barrier layer 101b includes a high refractive index material and may be formed adjacent to (e.g., directly on) barrier layer 101a. The high refractive index material may include any suitable barrier material, including, for example, any suitable absorption-free optical material, including, for example, tin oxide, zinc oxide, titanium oxide, niobium oxide, tantalum oxide or silicon nitride. Barrier layer 101c includes a low refractive index material and may be formed adjacent to (e.g., directly on) barrier layer 101b. The low refractive index material of barrier layer 101c may the same as or different than the low refractive index material of barrier layer 101a, and may include any suitable barrier material, including, for example, silicon oxide, aluminum-doped silicon oxide or silicon oxynitride. Each of barrier layers 101a, 101b, 101c may be formed or deposited using any suitable method, including, for example, sputtering.

Barrier layers 101a, 101b, 101c may be formed to any suitable thickness. Each of barrier layers 101a, 101b, 101c may have a thickness of more than about 10 nm, more than about 20 nm, more than about 50 nm, more than about 100 nm, more than about 150 nm, less than about 500 nm, less than about 300 nm, less than about 250 nm, or less than about 200 nm. The thickness of any one or more of barrier layers 101a, 101b, 101c may be controlled (or fixed) in order to improve performance of a resulting photovoltaic device. For example, the thickness of barrier layer 101a may be fixed at a minimum barrier thickness in order to control the diffusion of mobile ions from substrate 100. Appropriate thicknesses of barrier layer 101b and barrier layer 101c can be determined with proper coating design by one of skill in the art in order to maximize the benefits of color suppression and sunnyside reflection loss. To do this, barrier tri-layer 103 may be included as part of a constrained stack that is optimized such that only the thicknesses of barrier layers 101b, 101c may be varied (to have either slight or substantial variation from the thickness of barrier layer 101a). In one example embodiment, barrier tri-layer 103 includes low refractive index barrier layer 101a having a thickness of more than about 10 nm and less than about 500 nm, more particularly more than about 50 nm and less than about 200 nm, more particularly a thickness of about 100 nm and is formed of an aluminum-doped silicon oxide.

Transparent conductive oxide layer 112 is foamed of any suitable material, including, for example, cadmium indium oxide, indium tin oxide, cadmium stannate or zinc aluminum oxide. Transparent conductive oxide layer 112 may be formed or deposited using any suitable method, including, for example, sputtering. Transparent conductive oxide layer 112 may have any suitable thickness, including, for example, more than about 10 nm, more than about 20 nm, more than about 50 nm, more than about 100 nm, more than about 150 nm, less than about 500 nm, less than about 300 nm, less than about 250 nm, or less than about 200 nm. The transparent conductive oxide layer 112 may include a sheet resistance of below about 15 ohm/square, and more particularly below about 10 ohm/square, below about 9 ohm/square, or below about 6 ohm/square. The transparent conductive oxide layer 112 may have an average optical absorption of less than about 4% between about 400 nm to about 850 nm as a front contact of a photovoltaic device. Cadmium stannate functions well in this capacity, as it exhibits high optical transmission and low electrical sheet resistance.

Buffer layer 114 is formed of any suitable material, including, for example, tin oxide, zinc oxide, zinc tin oxide, indium oxide, titanium oxide, niobium oxide, tantalum oxide and silicon nitride. Buffer layer 114 may be formed or deposited using any suitable method, including, for example, sputtering. Buffer layer 114 may have any suitable thickness, including, for example, more than about 10 nm, more than about 20 nm, more than about 50 nm, more than about 100 mu, more than about 150 nm, less than about 500 nm, less than about 300 nm, less than about 250 nm, or less than about 200 nm.

Barrier tri-layer 103, transparent conductive oxide layer 112 and buffer layer 114 form part of a transparent conductive oxide stack 130, which may serve as a front contact of a photovoltaic device. Transparent conductive oxide stack 130 may be annealed to form an annealed transparent conductive oxide stack, following deposition of the various layers included therein.

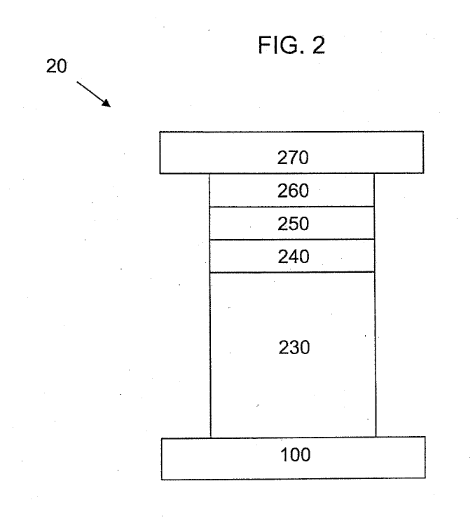

FIG. 2 illustrates an example embodiment of a photovoltaic device 20 including an annealed transparent conductive oxide stack 230. One or more layers may be formed adjacent to the annealed transparent conductive oxide stack 230. For example, one or more semiconductor device layers may be deposited on the annealed stack to form photovoltaic cell. The semiconductor layers may include one or more active layers. For example, a layer of cadmium, indium, gallium and selenium (CIGS) may be incorporated into the structure. Alternatively, a semiconductor window layer and semiconductor absorber layer may be incorporated into the structure. In the embodiment shown in FIG. 2, semiconductor window layer 240 is formed adjacent the annealed transparent conductive oxide stack 230 and semiconductor absorber layer 250 is formed adjacent the semiconductor window layer 240. In one example embodiment, semiconductor window layer 240 may be formed of any suitable semiconductor material, including for example, cadmium sulfide and semiconductor absorber layer 250 may be formed of any suitable semiconductor material, including for example, cadmium telluride. Window layer 240 and absorber layer 150 may be formed using any suitable deposition technique, including, for example, vapor transport deposition. A back contact 260 is formed adjacent to absorber layer 250. Back contact 260 may include any suitable contact material, including, for example, molybdenum. Back contact 260 may be deposited using any suitable deposition technique, including, for example, sputtering. A back support 270 is deposited adjacent to back contact 260. Back support 270 may include any suitable material, including, for example, a glass (e.g., a soda-lime glass).

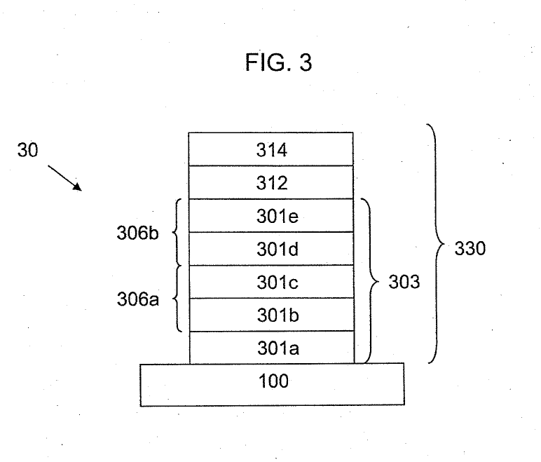

While the embodiment illustrated in FIG. 1 includes a single barrier bi-layer (e.g., barrier layers 101b, 101c), one or more additional barrier bi-layers may be incorporated into the multilayered structure in order to further improve device performance. As seen in the example embodiment of FIG. 3, the barrier layer structure 303 includes barrier layer 301a, first barrier bi-layer 306a and second barrier bi-layer 306b. Barrier layer 301a is a low refractive index barrier layer and may be formed of any suitable materials, at any suitable thickness, as discussed previously with respect to barrier layer 101a. Barrier layer 301a may be fowled adjacent to substrate 200, which, like substrate 100 from FIG. 1, may include any suitable substrate material, including, for example, glass (e.g., soda-lime glass). Barrier layer 301b may be formed adjacent to (e.g., directly on) barrier layer 301a. Barrier layer 301c may be formed adjacent to (e.g., directly on) barrier layer 301b. Barrier layer 301b and barrier layer 301c together form barrier bi-layer 306a. Barrier layer 301d may be formed adjacent to (e.g., directly on) barrier layer 301c. Barrier layer 301e may be formed adjacent to (e.g., directly on) barrier layer 301d. Barrier layer 301d and barrier layer 301e together form barrier bi-layer 306b.

Barrier layers 301b, 301d are high refractive index barrier layers of the first and second barrier bi-layers 306a, 306b, respectively. Barrier layers 301b, 301d may be formed of any suitable materials, at any suitable thickness, as discussed previously with respect to high refractive index barrier layer 101b. Barrier layers 301c, 301e are low refractive index barrier layers of the first and second barrier bi-layers 306a, 306b, respectively. Barrier layers 301c, 301e may be formed of any suitable materials, at any suitable thickness, as discussed previously with respect to high refractive index barrier layer 101c. One or more barrier layers 303 may include one or more additional barrier bi-layers, consisting of any suitable arrangement of barrier materials, including, for example, alternating high and low refractive index materials. Any one of one or more barrier layers 303 may be deposited using any suitable technique, including, for example, sputtering.

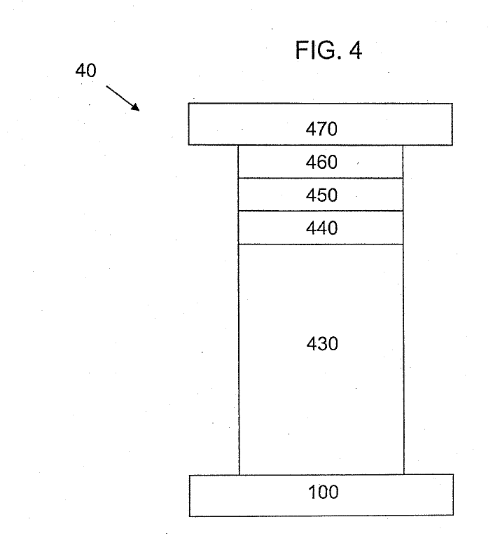

Following deposition of one or more barrier layers 303, transparent conductive oxide layer 312 and buffer layer 314 are formed adjacent thereto. One or more barrier layers 303, transparent conductive oxide layer 312 and buffer layer 314 may be part of a transparent conductive oxide stack 330. As discussed above with respect to FIG. 2, following deposition of the various layers therein, transparent conductive oxide stack 330 may be annealed to form an annealed stack 430, seen in the example embodiment shown in FIG. 4.

As discussed with respect to FIG. 2, one or more layers may be formed adjacent to the annealed transparent conductive oxide stack 430. In the example embodiment of FIG. 4, a cadmium sulfide layer 440 is formed adjacent to an annealed stack 430 and a cadmium telluride layer 450 is formed adjacent to cadmium sulfide layer 440. Alternatively, layer of cadmium, indium, gallium and selenium (CIGS) may be incorporated into the structure instead of the cadmium telluride and cadmium sulfide layers. A back contact 460 is deposited adjacent to cadmium telluride layer 450. Back contact 460 may include any suitable material, including, for example, molybdenum. A back support 470 is deposited adjacent to back contact 460. Back contact 460 may include any suitable material, including, for example, glass (e.g., soda-lime glass).

Any of the layers shown in FIGS. 1-4 may be formed using any suitable technique or combination of techniques. For example, any of the aforementioned layers can be formed by low pressure chemical vapor deposition, atmospheric pressure chemical vapor deposition, plasma-enhanced chemical vapor deposition, thermal chemical vapor deposition, DC or AC sputtering, spin-on deposition or spray-pyrolysis. Each deposition layer can be of any suitable thickness, for example in the range of about 1 to about 5000 A.

The disclosed embodiments each include built-in high refractive index-low refractive index bi-layers (e.g., 101b-101c (FIG. 1), 306a and 306b (FIG. 3)) in multilayered structure 230, 430. With the built-in high refractive index-low refractive index bi-layers, interference near the spectrum of visible light may be substantially reduced. Thus, a photovoltaic device incorporating such a multilayered structure may exhibit various improved performance characteristics, including, for example, improved color suppression and reflection reduction (thus more light transmitted to the semiconductor junction for electricity generation).

The benefits of incorporating high refractive index-low refractive index bi-layers can be verified via both optical modeling and experimental measurements. With the built-in bi-layer, the magnitudes of interference peaks in reflection dispersions of the multilayered structure and its associated thin-film photovoltaic device may decrease substantially. This can lead to a more uniform color appearance of the photovoltaic device. It may also help mitigate the localized contrast that may arise from any irregularities of the semiconductor layers. Moreover, the addition of the bi-layer can result in reduced average reflection loss in the visible light spectrum. Thus, more light transmits to the p-n junction for electricity generation, resulting in increased efficiency for the photovoltaic device.

Photovoltaic devices/cells fabricated using the methods discussed herein may be incorporated into one or more photovoltaic modules. The modules may be incorporated into various systems for generating electricity. For example, a photovoltaic cell may be illuminated with a beam of light to generate a photocurrent. The photocurrent may be collected and converted from direct current (DC) to alternating current (AC) and distributed to a power grid. Light of any suitable wavelength may be directed at the cell to produce the photocurrent, including, for example, more than 350 nm, or less than 850 nm. Photocurrent generated from one photovoltaic cell may be combined with photocurrent generated from other photovoltaic cells. For example, the photovoltaic cells may be part of one or more photovoltaic modules in a photovoltaic array, from which the aggregate current may be harnessed and distributed.

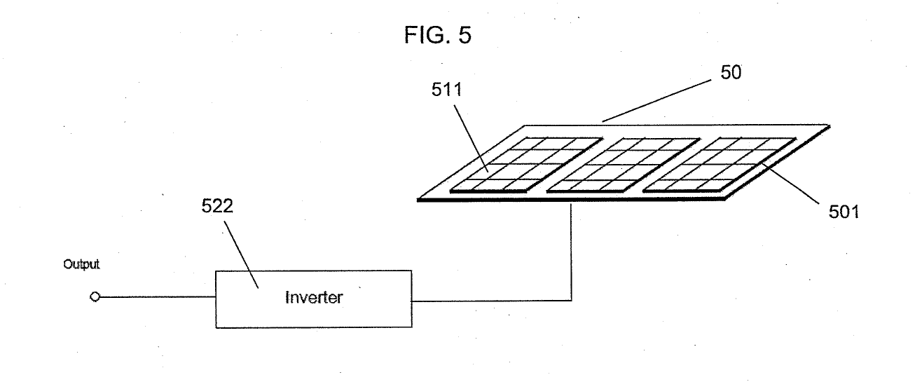

Referring to FIG. 5, by way of example, a photovoltaic array 50 may include one or more interconnected photovoltaic modules 501. One or more of photovoltaic modules 501 may include one or more photovoltaic cells 511 having any of the multilayer structure or photovoltaic device configurations discussed herein. Photovoltaic array 50 may be illuminated with a light source, e.g., the sun or any suitable artificial light source, to generate a photocurrent. For example, photovoltaic array 50 may be illuminated with a wavelength of light between about 400 nm to about 700 nm. The generated photocurrent may be converted from direct current (DC) to alternating current (AC) using, for example, an inverter 522. The converted current may be output for any of a variety of uses, including, for example, connection to one or more home appliances or to a utility grid.

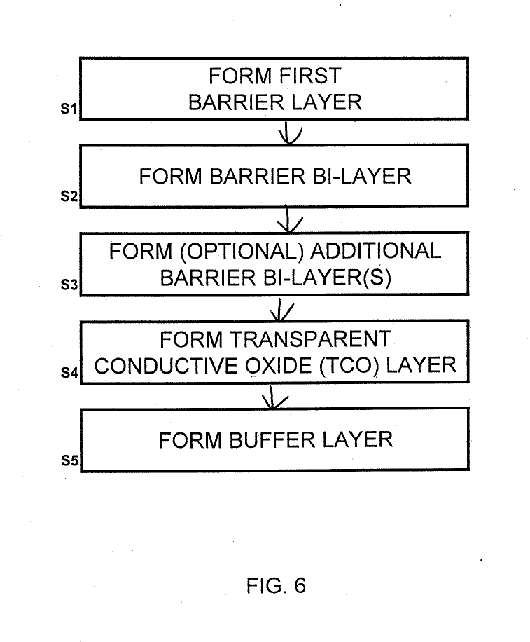

An example method of manufacturing a multilayered structure is illustrated in FIG. 6. In step S1, a first barrier layer is formed adjacent a substrate. In step S2, a barrier bi-layer, which includes a second barrier layer and a third barrier layer, is formed adjacent to the first barrier layer. The method may further include forming one or more additional barrier bi-layers adjacent to the first barrier bi-layer, as shown in optional step S3. Each of the one or more additional barrier bi-layers includes a first material having a higher refractive index than a second material thereof. In step S4, a transparent conductive oxide layer, which may be an amorphous transparent conductive oxide, is formed adjacent to the barrier bi-layer. In step S5, a buffer layer is formed adjacent to the transparent conductive oxide layer. The first barrier layer, barrier bi-layers, transparent conductive oxide layer and buffer layer form part of a transparent conductive oxide stack.

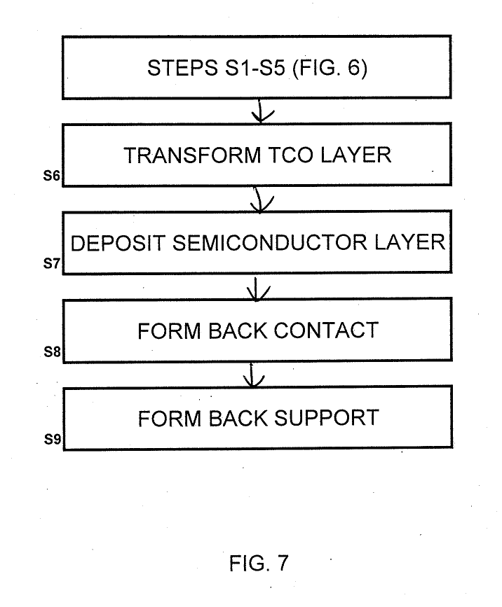

An example method of manufacturing a photovoltaic device is illustrated in FIG. 7. Steps S1 through S5 are the same as described with respect to FIG. 6. In step S6, the amorphous transparent conductive oxide is transformed into a crystalline transparent conductive oxide. In step S7, a semiconductor layer is deposited adjacent to the transparent conductive oxide stack. In step S8, a back contact is formed adjacent to the semiconductor layer. In step S9, a back support is deposited adjacent to back contact.

The depositing step S7 may include forming a cadmium sulfide layer adjacent to the buffer layer and forming a cadmium telluride layer adjacent to the cadmium sulfide layer. The depositing step S7 may alternatively include forming a layer of cadmium, indium, gallium and selenium (CIGS).

The transforming step S6 may occur before, during or after the deposition of the semiconductor layer in step S7. For example, the transforming step S6 may include annealing the transparent conductive oxide stack before deposition of the semiconductor layer. Transparent conductive oxide stack may be annealed at any suitable temperature, including, for example, more than about 38° C., more than about 50° C., more than about 60° C., less than about 80° C., and less than about 70° C., or less than about 65° C.

The transforming step S6 and deposition step S7 may alternatively include using vapor transport deposition to form a semiconductor bi-layer of cadmium sulfide and cadmium telluride adjacent to the transparent conductive oxide stack. The transforming step S6 and deposition step S7 may alternatively include using close space sublimation to form a semiconductor bi-layer of cadmium sulfide and cadmium telluride adjacent to the transparent conductive oxide stack.

The embodiments described above are offered by way of illustration and example. It should be understood that the examples provided above may be altered in certain respects and still remain within the scope of the claims. It should be appreciated that, while the invention has been described with reference to the above preferred embodiments, other embodiments are within the scope of the claims.

1. A multilayered structure comprising:
a first barrier layer adjacent to a substrate;
a barrier bi-layer adjacent to the first barrier layer, the barrier bi-layer comprising a second barrier layer and a third barrier layer;
a transparent conductive oxide layer adjacent to the barrier bi-layer, the transparent conductive oxide layer comprising a material selected from the group consisting of cadmium indium oxide and cadmium stannate; and
a buffer layer adjacent to the transparent conductive oxide layer.

2. The multilayered structure of claim 1, wherein the first barrier layer comprises a material having a lower refractive index than a refractive index of the second barrier layer.

3. The multilayered structure of claim 1, wherein the first barrier layer comprises a material selected from the group consisting of silicon oxide, aluminum-doped silicon oxide and silicon oxynitride.

4. The multilayered structure of claim 1, wherein the second barrier layer comprises a material having a higher refractive index than refractive indices of the first barrier layer and the third barrier layer.

5. The multilayered structure of claim 1, wherein the second barrier layer comprises a material selected from the group consisting of tin oxide, zinc oxide, titanium oxide, niobium oxide, tantalum oxide and silicon nitride.

6. The multilayered structure of claim 1, wherein the third barrier layer comprises a material having a lower refractive index than a refractive index of the second barrier layer.

7. The multilayered structure of claim 1, wherein the third barrier layer comprises a material selected from the group consisting of silicon oxide, aluminum-doped silicon oxide and silicon oxynitride.

8. (canceled)

9. The multilayered structure of claim 1, wherein the buffer layer comprises a material selected from the group consisting of tin oxide, zinc oxide, zinc tin oxide, indium oxide, titanium oxide, niobium oxide, tantalum oxide and silicon nitride.

10. The multilayered structure of claim 1, wherein any of the first barrier layer, second barrier layer or third barrier layer comprises a thickness of more than about 10 nm.

11. The multilayered structure of claim 1, wherein any of the first barrier layer, second bather layer or third barrier layer comprises a thickness of less than about 200 nm.

12. The multilayered structure of claim 1, wherein the transparent conductive oxide layer comprises a thickness of more than about 100 nm.

13. The multilayered structure of claim 1, wherein the transparent conductive oxide layer comprises a thickness of less than about 500 nm.

14. The multilayered structure of claim 1, wherein the buffer layer comprises a thickness of more than about 10 nm.

15. The multilayered structure of claim 1, wherein the buffer layer comprises a thickness of less than about 200 nm.

16. The multilayered structure of claim 1, further comprising one or more additional barrier bi-layers, each of the one or more additional barrier bi-layers comprising a first material adjacent to a second material, wherein the first material has a higher refractive index than the second material.

17. The multilayered structure of claim 16, wherein each one of the one or more additional barrier bi-layers comprises at least one layer selected from the group consisting of tin oxide, zinc oxide, titanium oxide, niobium oxide, tantalum oxide, silicon nitride, silicon oxide, aluminum-doped silicon oxide and silicon oxynitride.

18. The multilayered structure of claim 1, further comprising a cadmium sulfide layer adjacent to the buffer layer and a cadmium telluride layer adjacent to the cadmium sulfide layer.

19. The multilayered structure of claim 1, wherein the transparent conductive oxide layer comprises a sheet resistance of below about 15 ohm/square.

20. The multilayered structure of claim 1, wherein the transparent conductive oxide layer comprises a sheet resistance of below about 10 ohm/square.

21. The multilayered structure of claim 1, wherein the transparent conductive oxide layer comprises a sheet resistance of below about 6 ohm/square.

22. The multilayered structure of claim 1, wherein the transparent conductive oxide layer comprises an average optical absorption of less than about 4% between about 400 nm to about 850 nm as a front contact of a photovoltaic device.

23. A method of manufacturing a multilayered structure, the method comprising:
forming a barrier bi-layer adjacent to a first barrier layer on a substrate, the barrier bi-layer comprising a second barrier layer and a third barrier layer;
forming a transparent conductive oxide layer adjacent to the barrier bi-layer by depositing a material selected from the group consisting of cadmium indium oxide and cadmium stannate; and
forming a buffer layer adjacent to the transparent conductive oxide layer.

24. The method of claim 23, wherein forming a first barrier layer comprises depositing a material having a lower refractive index than a refractive index of the second barrier layer.

25. The method of claim 23, wherein forming a first barrier layer comprises depositing a material selected from the group consisting of silicon oxide, aluminum-doped silicon oxide and silicon oxynitride.

26. The method of claim 23, wherein forming a second barrier layer comprises depositing a material having a higher refractive index than refractive indices of the first barrier layer and the third barrier layer.

27. The method of claim 23, wherein forming a second barrier layer comprises depositing a material selected from the group consisting of tin oxide, zinc oxide, titanium oxide, niobium oxide, tantalum oxide and silicon nitride.

28. The method of claim 23, wherein forming a third barrier layer comprises depositing a material having a lower refractive index than a refractive index of the second barrier layer.

29. The method of claim 23, wherein forming a third barrier layer comprises depositing a material selected from the group consisting of silicon oxide, aluminum-doped silicon oxide and silicon oxynitride.

30. (canceled)

31. The method of claim 23, wherein forming a buffer layer comprises depositing a material selected from the group consisting of tin oxide, zinc oxide, zinc tin oxide, indium oxide, titanium oxide, niobium oxide, tantalum oxide and silicon nitride.

32. The method of claim 23, further comprising forming one or more additional barrier bi-layers adjacent to the first barrier bi-layer, each of the one or more additional barrier bi-layers comprising a first material adjacent to a second material, wherein the first material has a higher refractive index than a refractive index of the second material.

33. The method of claim 23, further comprising:
forming a cadmium sulfide layer adjacent to the buffer layer; and
forming a cadmium telluride layer adjacent to the cadmium sulfide layer.

34. A photovoltaic device comprising:
a first barrier layer adjacent to a substrate, the first barrier layer comprising a material selected from the group consisting of silicon oxide, aluminum-doped silicon oxide and silicon oxynitride;
a barrier bi-layer adjacent to the first barrier layer, the barrier bi-layer comprising a second barrier layer and a third barrier layer, wherein the second barrier layer comprises a material selected from the group consisting of tin oxide, zinc oxide, titanium oxide, niobium oxide, tantalum oxide and silicon nitride, and wherein the third barrier layer comprises a material selected from the group consisting of silicon oxide, aluminum-doped silicon oxide and silicon oxynitride;
a transparent conductive oxide layer adjacent to the barrier bi-layer, wherein the transparent conductive oxide layer comprises a material selected from the group consisting of cadmium indium oxide and cadmium stannate;
a buffer layer adjacent to the transparent conductive oxide layer, wherein the buffer layer comprises a material selected from the group consisting of tin oxide, zinc oxide, zinc tin oxide, indium oxide, titanium oxide, niobium oxide, tantalum oxide and silicon nitride;
a cadmium sulfide layer adjacent to the buffer layer; and
a cadmium telluride layer adjacent to the cadmium sulfide layer.

35. A method of manufacturing a multilayered structure, the method comprising:
forming a stack, comprising the steps of:
forming a barrier bi-layer adjacent to a first barrier layer on a substrate, the first barrier layer comprising a material selected from the group consisting of silicon oxide, aluminum-doped silicon oxide and silicon oxynitride, the barrier bi-layer comprising a second barrier layer and a third barrier layer, wherein the second barrier layer comprises a material selected from the group consisting of tin oxide, zinc oxide, titanium oxide, niobium oxide, tantalum oxide and silicon nitride and wherein the third barrier layer comprises a material selected from the group consisting of silicon oxide, aluminum-doped silicon oxide and silicon oxynitride;
forming an amorphous oxide adjacent to the barrier bi-layer, wherein the amorphous oxide comprises a material selected from the group consisting of cadmium indium oxide and cadmium stannate; and
forming a buffer layer adjacent to the transparent conductive oxide layer, wherein the buffer layer comprises a material selected from the group consisting of tin oxide, zinc oxide, zinc tin oxide, indium oxide, titanium oxide, niobium oxide, tantalum oxide and silicon nitride; and
transforming the amorphous oxide into a crystalline transparent conductive oxide before, during or after deposition of a semiconductor layer adjacent to the stack.

36. The method of claim 35, further comprising forming one or more additional barrier bi-layers adjacent to the first barrier bi-layer, each of the one or more additional barrier bi-layers comprising a first material adjacent to a second material, wherein the first material has a higher refractive index than a refractive index of the second material.

37. The method of claim 35, wherein the transforming comprises annealing the stack before deposition of the semiconductor layer.

38. The method of claim 35, wherein the transforming comprises using vapor transport deposition to form a semiconductor bi-layer of cadmium sulfide and cadmium telluride adjacent to the stack.

39. The method of claim 35, wherein the transforming comprises using close space sublimation to form a semiconductor bi-layer of cadmium sulfide and cadmium telluride adjacent to the stack.

40. The method of claim 35, wherein the crystalline transparent conductive oxide comprises a sheet resistance of below about 15 ohm/square.

41. The method of claim 35, wherein the crystalline transparent conductive oxide comprises a sheet resistance of below about 10 ohm/square.

42. The method of claim 35, wherein the crystalline transparent conductive oxide comprises a sheet resistance of below about 6 ohm/square.

43. The method of claim 35, wherein the crystalline transparent conductive oxide comprises an average optical absorption of less than about 4% between about 400 nm to about 850 nm as a front contact of a photovoltaic device.

44. A photovoltaic module comprising:
a plurality of photovoltaic cells adjacent to a substrate; and
a back cover adjacent to the plurality of photovoltaic cells, the plurality of photovoltaic cells comprising:
a first barrier layer adjacent to a substrate;
a barrier bi-layer adjacent to the first barrier layer, the barrier bi-layer comprising a second barrier layer and a third barrier layer;
a transparent conductive oxide layer adjacent to the barrier bi-layer, the transparent conductive oxide layer comprising a material selected from the group consisting of cadmium indium oxide and cadmium stannate;
a buffer layer adjacent to the transparent conductive oxide layer;
a cadmium sulfide layer adjacent to the buffer layer; and
a cadmium telluride layer adjacent to the cadmium sulfide layer.

45. A method for generating electricity, the method comprising:
illuminating a photovoltaic cell with a beam of light to generate a photocurrent; and
collecting the generated photocurrent, wherein the photovoltaic cell comprises:
a first barrier layer adjacent to a substrate;
a barrier bi-layer adjacent to the first barrier layer, the barrier bi-layer comprising a second barrier layer and a third barrier layer;
a transparent conductive oxide layer adjacent to the barrier bi-layer, the transparent conductive oxide layer comprising a material selected from the group consisting of cadmium indium oxide and cadmium stannate;
a buffer layer adjacent to the transparent conductive oxide layer;
a cadmium sulfide layer adjacent to the buffer layer; and
a cadmium telluride layer adjacent to the cadmium sulfide layer.

46. A multilayered substrate comprising:
a first barrier layer adjacent to a glass, the first barrier layer comprising a material selected from the group consisting of silicon oxide, aluminum-doped silicon oxide and silicon oxynitride;
a barrier bi-layer adjacent to the first barrier layer, the barrier bi-layer comprising a second barrier layer and a third barrier layer, wherein the second barrier layer comprises a material selected from the group consisting of tin oxide, zinc oxide, titanium oxide, niobium oxide, tantalum oxide and silicon nitride and wherein the third barrier layer comprises a material selected from the group consisting of silicon oxide, aluminum-doped silicon oxide and silicon oxynitride;
a transparent conductive oxide layer adjacent to the barrier bi-layer, wherein the transparent conductive oxide layer comprises a material selected from the group consisting of cadmium indium oxide and cadmium stannate; and
a buffer layer adjacent to the transparent conductive oxide layer, wherein the buffer layer comprises a material selected from the group consisting of tin oxide, zinc oxide, zinc tin oxide, indium oxide, titanium oxide, niobium oxide, tantalum oxide and silicon nitride.

47. A multilayered substrate comprising:
a barrier layer structure comprising:
a plurality of barrier layers being alternating layers of low refractive index material and high refractive index material;
a transparent conductive oxide layer adjacent to the barrier bi-layer, the transparent conductive oxide layer comprising a material selected from the group consisting of cadmium indium oxide and cadmium stannate; and
a buffer layer adjacent to the transparent conductive oxide layer.
